(19) United States
(12) Patent Application Publication
(10) Pub. No.: US 2025/0254828 A1
(43) Pub. Date: Aug. 7, 2025

(54) Hybrid capillary-driven phase-change micro-cooler having passive coolant recirculation

(71) Applicant: The Board of Trustees of the Leland Stanford Junior University, Stanford, CA (US)

(72) Inventors: Yujui Lin, Stanford, CA (US); Heungdong Kwon, Stanford, CA (US); Mehdi Asheghi, Oakland, CA (US); Kenneth E. Goodson, Portola Valley, CA (US)

(21) Appl. No.: 19/042,817

(22) Filed: Jan. 31, 2025

Related U.S. Application Data
(60) Provisional application No. 63/549,291, filed on Feb. 2, 2024.

(51) Int. Cl. H05K 7/20

(52) U.S. Cl. CPC H05K 7/20336

(57) ABSTRACT

Improved cooling performance is provided using a two-phase cooler designed such that most of the coolant evaporates and condenses in operation. The evaporator includes microchannels and a hydrophilic surface structure to enhance capillary-driven flow by wicking. Coolant vapor hitting the condenser is condensed and recirculated to the evaporator. Preferably, this recirculation is in a sealed vapor chamber with no pumping of the coolant. A coolant flow structure can be included on top of the evaporator to facilitate coolant flow to hot spots on the evaporator and to facilitate vapor flow away from these hot spots.

### CROSS REFERENCE TO RELATED APPLICATIONS

This application claims priority from U.S. Provisional Patent Application 63/549,291 filed Feb. 2, 2024, which is incorporated herein by reference.

### GOVERNMENT SPONSORSHIP

This invention was made with Government support under contract 1449548 awarded by the National Science Foundation. The Government has certain rights in the invention.

### FIELD OF THE INVENTION

This invention relates to cooling of heat-generating devices.

### BACKGROUND

As technology evolves, providing sufficient heat sinking for devices is increasingly challenging. One conventional approach is liquid cooling, where a recirculating flow of coolant is used to transfer heat away from the devices being cooled. Such systems tend to be designed for single-phase operation, and will fail or have degraded performance if a significant fraction of the coolant is vaporized.

Two-phase systems have also been considered, where vaporization of the coolant is accounted for in the design. One motivation for such systems is to take advantage of high heats of vaporization provided by some coolants, e.g., water. However, such systems often encounter problems such as flooding or drying-out. In a flooding situation, too much fluid is present at the hot spots of the cooling system, thereby interfering with vapor generation and vapor transport which undesirably reduces the beneficial effect of heat of vaporization on system operation. In a drying-out situation, not enough coolant is present at hot spots of the cooling system, which typically leads to sharply degraded performance. Thus it would be an advance in the art to provide two-phase cooling with improved performance.

### SUMMARY

The main idea of this work is a heat exchanger having open microchannels with porous hydrophilic structures and two-phase flow. Coolant flow into the structure is capillary-driven.

In one example, we consider an embedded microcooler with a novel design that relies on capillary-wicking in open microchannels with hydrophilic copper porous (dendrite) structures. We start with copper microchannels followed by electroplating of copper at a high current density, where the dendrite structure forms the hydrophilic wicking surface. The thermal tests of the capillary-based microchannel cooler are conducted, where the dynamics of the liquid film formation and bubble departure in the microchannels are studied via high-speed imaging. The result shows the capillary-base two-phase cooler reaches an incredibly high heat flux of ˜700 W/cm², of which the superheat is ˜30° C., resulting in an extremely low two-phase thermal resistance of microcooler at ˜0.043 cm²-° C./W. The required flow rate to achieve such a cooling performance is less than 5 g/min, which is nearly two orders of magnitude smaller than the single-phase pumped flow in conventional microchannel cooling. Overall, the capillary-based two-phase microchannel cooler shows significant potential to advance the cooling performance and efficiency of the existing pumped-flow single-phase and two-phase microchannel coolers.

An exemplary embodiment includes: 1) a copper plate having open microchannels, where the microchannels and the copper plate have a surface coating of a hydrophilic dendrite wicking structure; and 2) a passive recirculation apparatus configured to receive output liquid coolant and output coolant vapor from the copper plate, configured to condense the output coolant vapor at a heat sink, and configured to provide the received output liquid coolant and condensed coolant vapor to the copper plate as an input coolant supply. Here coolant flow into the open microchannels is capillary-driven.

Preferably, 90% or more of the input coolant supply is condensed from coolant vapor at the heat sink. In other words, the preference is for nearly all the input coolant to the copper plate to be vaporized, thereby maximizing the benefit obtained from the heat of vaporization of coolant. The resulting performance can be excellent. For example, in one exemplary embodiment having water as the coolant, a heat flux of 600 W/cm² or more can be delivered to the heat sink from the copper plate at a flow rate of the input water supply of 5 g/min or less.

Practice of the invention does not depend critically on the coolant employed, although water is of particular interest for its unusually high heat of vaporization. Another coolant of specific interest is CF₃CH₂CHF₂ (R245fa). When water is the coolant, the apparatus is preferably configured such that an operating temperature of the heat sink is 50° C. or more. When R245fa is the coolant, the apparatus is preferably configured such that an operating temperature of the heat sink is 10° C. or more. More generally, the heat sink temperature should be somewhat below the boiling point of the coolant (e.g., between 5° C. and 50° C. lower than the boiling point of the coolant) so that vapor can be condensed and recirculated to the copper plate.

The passive recirculation apparatus is preferably configured as a sealed vapor chamber.

The apparatus can be configured to be integrated with the back side of a direct bond copper substrate of a power electronics module.

The passive recirculation apparatus can include a sponge configured to act as a reservoir. Suitable sponges include, but are not limited to porous polyurethane sponges.

The microchannels preferably have a width for coolant flow at least 10× a thickness of the hydrophilic dendrite wicking structure.

In a preferred embodiment, the apparatus can further include a coolant flow structure disposed on top of the open microchannels. Such a coolant flow structure can include one or more metal mesh layers. The one or more metal mesh layers can include one or more vent regions of reduced mesh density disposed to coincide with hot spots from operation of one or more heat-generating devices. This helps vapor escape from the mesh layers to reach the heat sink. Preferably, the one or more metal mesh layers have a total thickness that is larger than 2× a depth of the open microchannels. Preferably, the one or more metal mesh layers have a total thickness that is larger than 50× a thickness of the hydrophilic dendrite wicking structure.

### BRIEF DESCRIPTION OF THE DRAWINGS

FIGS. 1A-C show several views of a first embodiment of the invention.

FIGS. 2A-D show several views of a second embodiment of the invention.

FIGS. 3A-C show several views of a third embodiment of the invention.

FIG. 4 shows an interior view of the embodiment of FIGS. 3A-C.

FIG. 5 shows an exterior view of the embodiment of FIGS. 3A-C.

FIGS. 6A-B show SEM images of fabricated microchannels before and after fabrication of the hydrophilic wicking structure.

FIGS. 7A-B show SEM images of the hydrophilic wicking structure at the bottom of a microchannel and between microchannels.

FIG. 8 shows an example of measured cooling performance.

### DETAILED DESCRIPTION

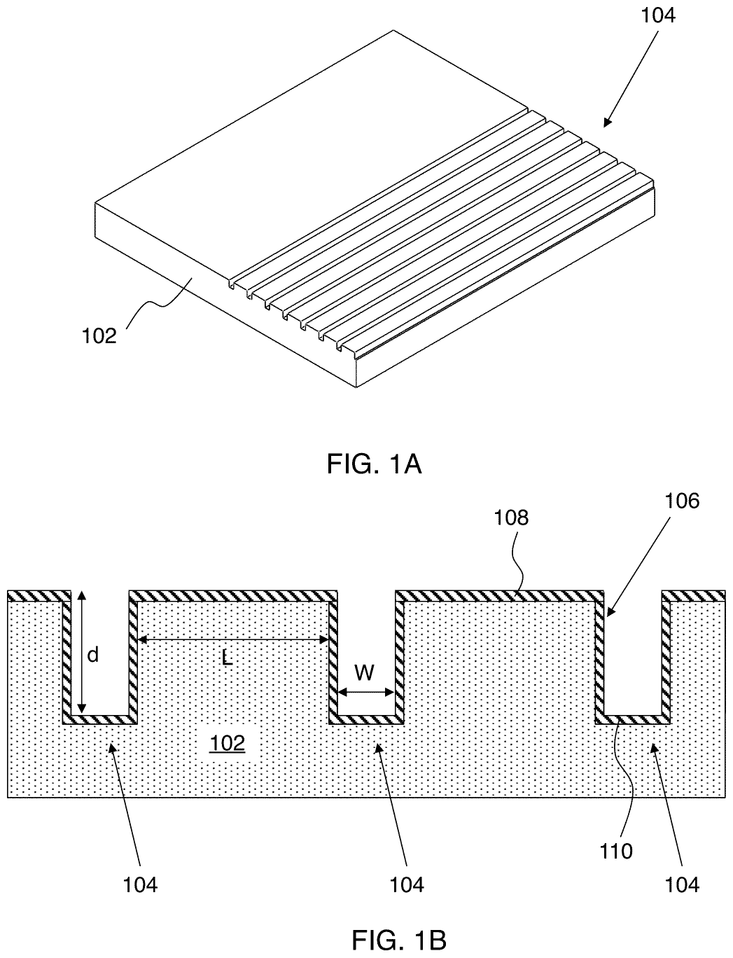

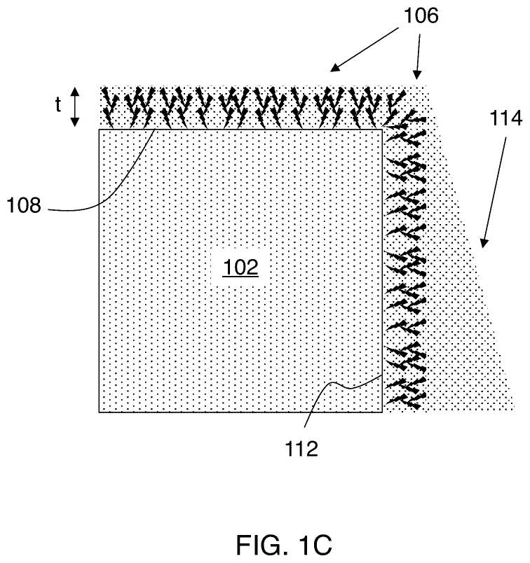

FIG. 1A shows microchannels 104 embedded in the copper layer 102 for the capillary-driven two-phase micro-cooler (sometimes referred to as capillary μcooler). FIG. 1B is the cross-sectional view. The microchannels 104 in the copper substrate 102 can be fabricated using saw cutting. The tool program defines the depth d of the open channels and the pitch between the channels L. The width of the cutting blade defines the channel width W.

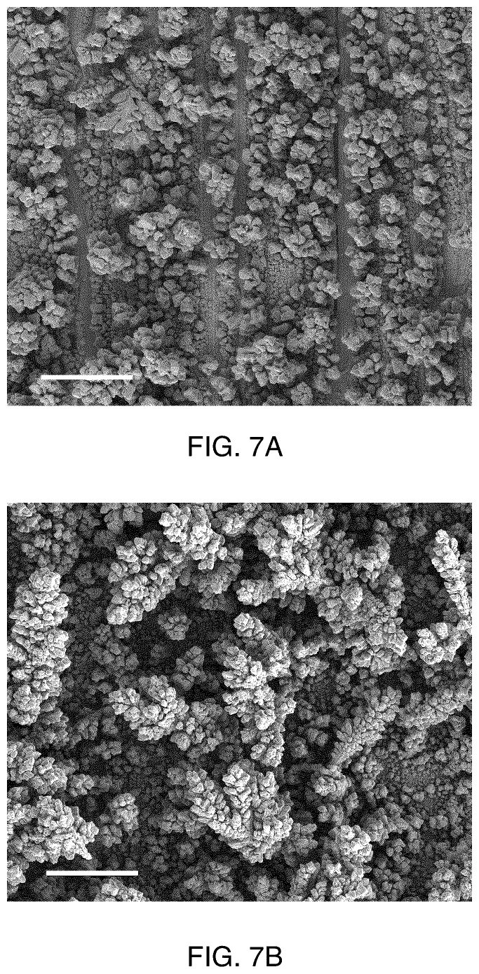

The microchannels then undergo surface modifications (e.g., electroplating) to create a layer 106 with a hydrophilic wicking structure. The high current density electroplating forms the dendrite structure on the channel surfaces. The morphology of the wicking structure at the bottom surfaces 110 of the microchannels is different from that at the top surface 108 of the copper substrate, as shown below on FIGS. 7A-B. Such wicking structures can wick both coolants considered in this work, water and CF₃CH₂CHF₂.

FIG. 1C shows a close-up view of the microchannel near the top surface 108 of the copper substrate 102. The dendrite hydrophilic wicking structure 106 has a much smaller thickness t (e.g., on the scale of roughly 10 μm) compared to the depth d of the microchannel (e.g., on the order of 100 μm). The purpose of this wicking surface coating is to maintain a thin liquid film at the top surfaces 108 and side surfaces 112 of the microchannels for enhanced phase change cooling. An exemplary profile of the liquid film at the surface is shown by 114.

The large capillary pressure created by the hydrophilic wicking structure overcomes the viscous pressure drop in the microchannel and wicks, enabling efficient liquid delivery. The microchannels are preferably wide (compared to the wick structure thickness) presenting less viscous resistance (pressure drop) to facilitate the delivery of liquid supply to hot spots of the heating section.

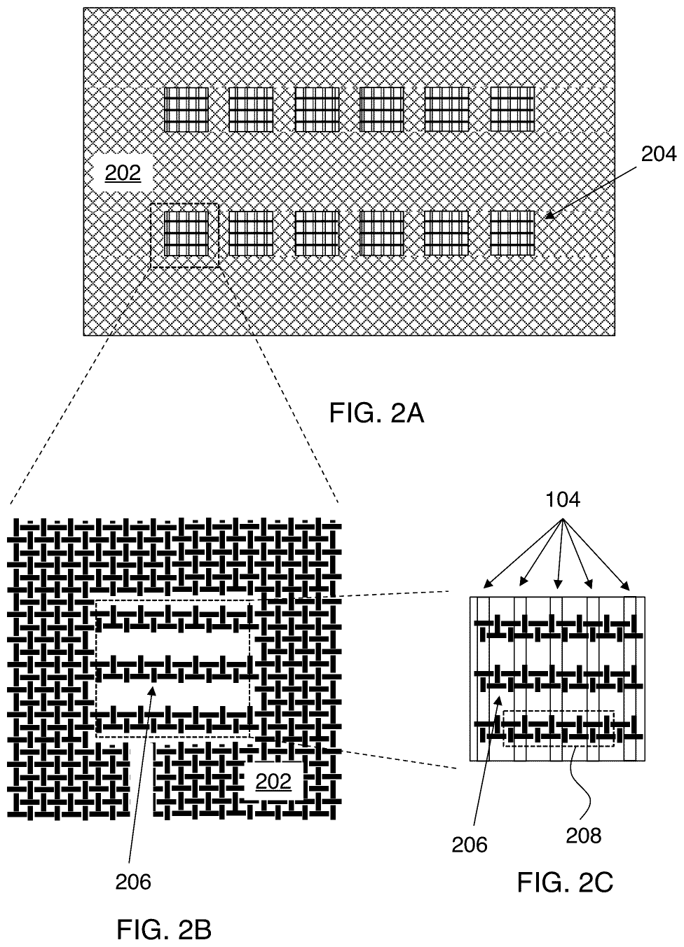

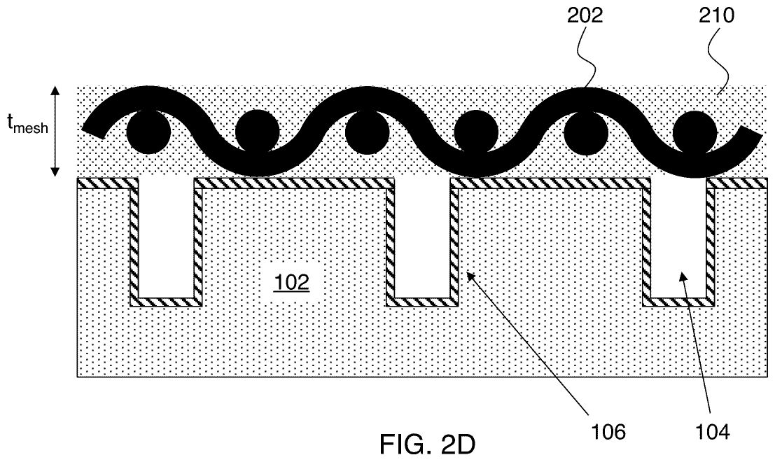

FIGS. 2A-D show an exemplary embodiment where a mesh structure is used to promote liquid flow to the microchannels. The basic configuration is that the mesh structure is disposed on top of the microchannels (as seen in the cross section view of FIG. 2D), but it is convenient to first describe the top views of FIGS. 2A-C which better show the features of the mesh.

FIG. 2A shows an alternative configuration to improve the liquid delivery to the microchannels. A copper wire mesh 202 is disposed on top of the microchannels. Mesh 202 can be patterned (e.g., by laser cutting) to include openings 204 at the hot spots from operation of one or more heat-generating devices. Such openings can provide a vapor pathway. FIG. 2B shows a close-up view of an opening 204. Bridges 206 formed by wire mesh 202 can carry liquid and improve the liquid supply to the microchannels, and the gaps between the bridges provide the vapor pathway. FIG. 2C shows a close-up view of the configuration of the wire mesh bridges 206 on top of the microchannels 104. Here 208 marks the location of the following cross section view.

FIG. 2D shows the cross-sectional view at 208 on FIG. 2C. Here wire mesh 202 is disposed on substrate 102, which results in mesh 202 being on top of the microchannels 104 that are covered by dendritic wicking structure 106. Mesh 202 can carry the liquid and form a thin liquid film 210. The liquid can transfer from wire mesh 202 to the wicking layer 106 by physical contact. The larger thickness (tₘₑₛₕ) of this liquid film compared to the wicking structure thickness (t) and the microchannel depth (d) ensures abundant liquid supply to hot spots. For example, typical dimensions are tₘₑₛₕ˜1 mm, t˜10 μm, and d˜100 μm). Thus this mesh structure can help prevent hot spots from drying out (which would impair cooling performance). Note that these three parameters are not shown to scale on FIG. 2D.

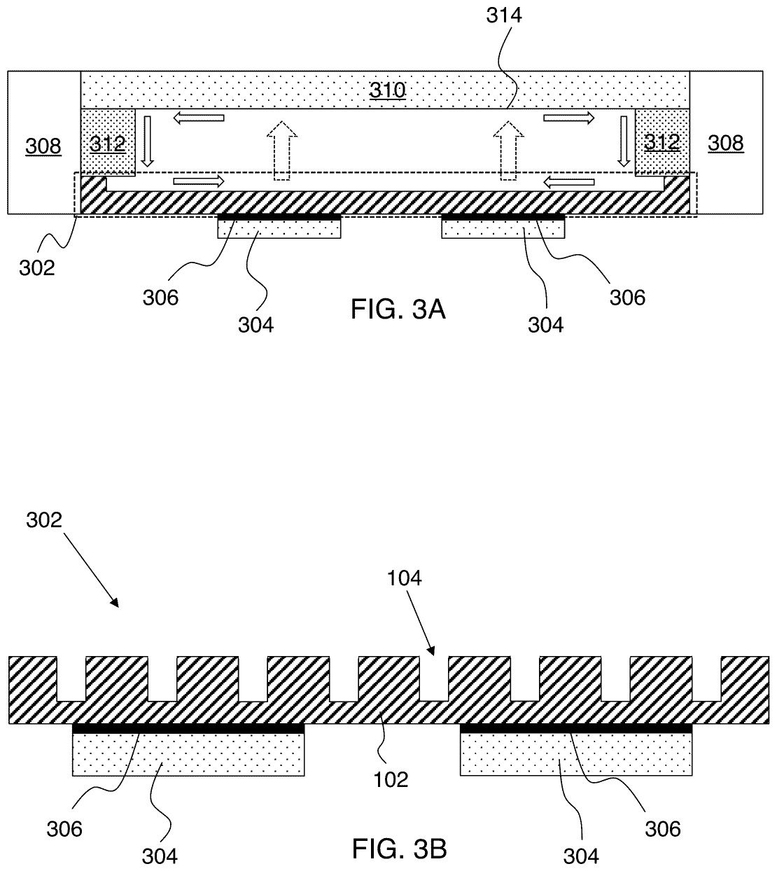

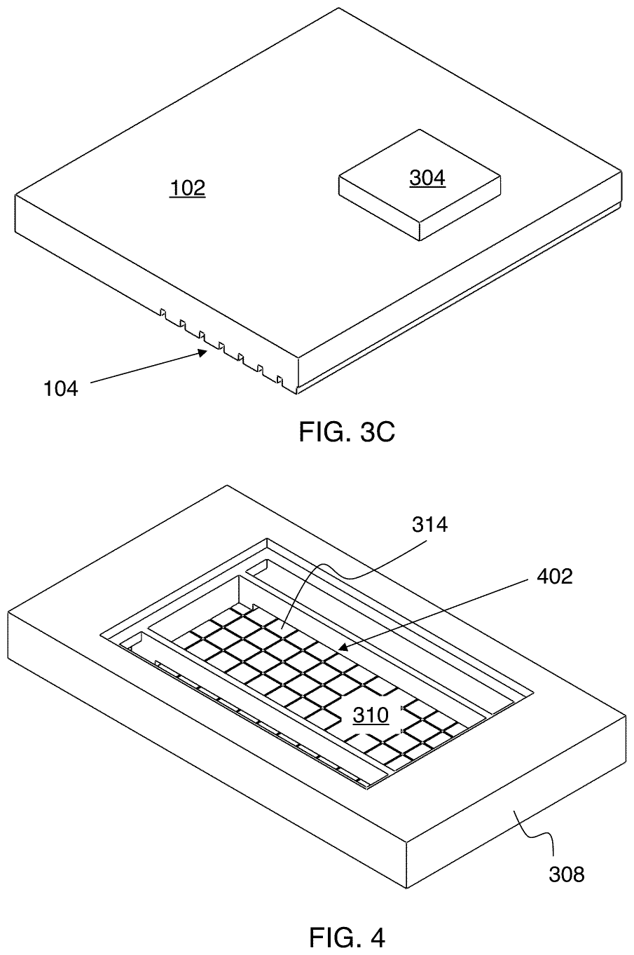

FIG. 3A is a cross section view that shows an exemplary embodiment where a microchannel plate is incorporated into a sealed vapor chamber to provide a package with an embedded capillary-based 2-phase cooler. Here 302 is a microchannel plate as described above and it is an integral part of the package substrate. Devices 304 are soldered to the backside of cooler 302 via solder 306. This vapor chamber includes a holder frame 308 that laterally encloses microchannel plate 302 and condenser 310 for coolant circulation. Condenser 310 has a downward-facing (on FIG. 3A) condensation surface 314. A local reservoir 312, which can, for example, be a porous polyurethane sponge can also be enclosed in the package to provide a buffer zone of the liquid supply to the microchannel. Such buffer zones can eliminate excessive liquid entering the microchannels, thus reducing flooding and improving the 2-phase cooling performance.

FIG. 3B is a close up view showing the main parts of microchannel plate 302, namely substrate 102 and microchannels 104. The microchannels 104 are embedded in the copper substrate 102 as part of the evaporator structure. FIG. 3C shows devices 304 packaged to the substrate 102. This direct integration of the microchannels into the package substrate for 2-phase cooling can eliminate the interfacial thermal resistance and lead to improved cooling performance.

Operation of this embodiment is schematically shown by the block arrows on FIG. 3A (dashed-line arrows for vapor flow, and solid-line arrows for liquid flow). The liquid in the microchannels is driven by capillary action in the hydrophilic wicking layer to flow to the hot spots caused by devices 304. There, most of the liquid is evaporated and ends up condensing on condenser 310 (which thus acts as a heat sink). To aid in this part of the operation, condenser 310 can be actively cooled (not shown) at its top surface. The main benefit of having a vapor chamber instead of directly putting devices 304 on heat sink 310 is that the heat is laterally distributed by the vapor chamber, which increases the amount of heat that can be removed for a specified maximum temperature rise of devices 304.

We designed the system to operate at a liquid temperature close to the phase change temperature (The saturation temperature). Note that for the closed loop system, we cannot control the inlet temperature, but it should be close to the phase change temperature. In general, the operating temperature will be a function of both surface temperature of (314) (T_surface condenser) (also a function of T_cold condenser) and surface temperature of (302) (T_Evaporator). We also target a high heat sink temperature of 50° C. or more when water is the coolant liquid. In a closed loop system this will result in the water input to the microchannels being in substantially the same temperature range.

FIG. 4 is an interior view showing the sample cooling package, where the view is looking up toward condenser 310 from microcooler 302 so that condensation surface 314 is visible. Condenser 310 has a metal condensation surface 314 that sits on top of the holder frame 308 (in this view) for vapor recovery and coolant circulation. One or more grooves 402 can be embedded into condenser 310 to promote liquid circulation to the local reservoir (312 on FIG. 3A). Condenser 310 can be soldered or otherwise affixed to one or more liquid-cooled cold plates (on its opposite side, not shown) to control the condensation temperature.

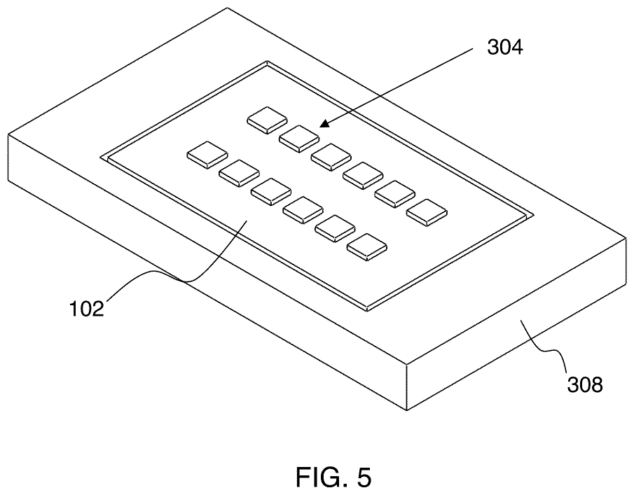

FIG. 5 shows the cooling package with the device side facing up. The devices 304 are packaged to the substrate 102, where the microchannels is embedded on the backside of the substrate to provide an evaporator structure as described above.

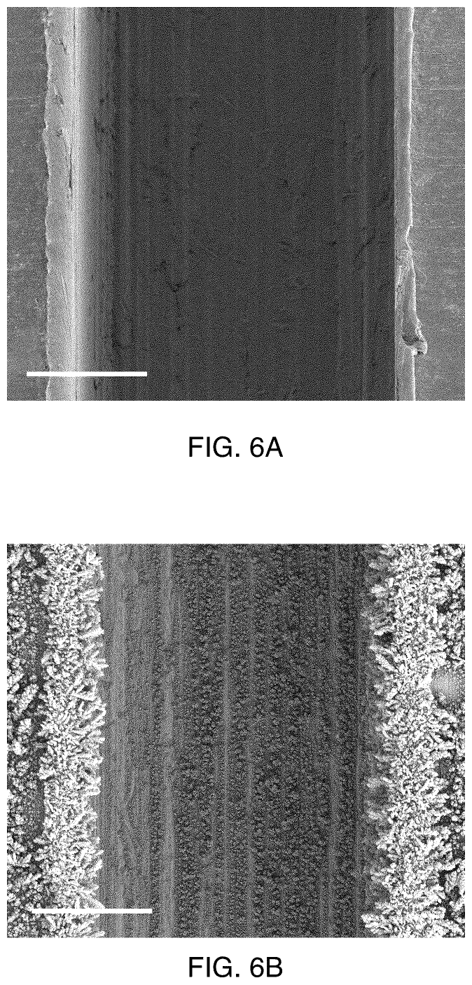

FIG. 6A shows a Scanning Electron Microscope (SEM) image of the channel 104 embedded in the copper substrate 102. FIG. 6B shows the channel surface after surface modification to provide a porous copper hydrophilic wicking structure 106. The scale bar on FIGS. 6A-B is 100 μm.

FIG. 7A shows an SEM image of the electroplated wicking surface 106 at the bottom surface 110 of the microchannel 104 embedded in the copper substrate 102. FIG. 7B shows an SEM image of the porous copper structure 106 at the top surface 108 between the microchannels 104. The scale bar on FIGS. 7A-B is 10 μm.

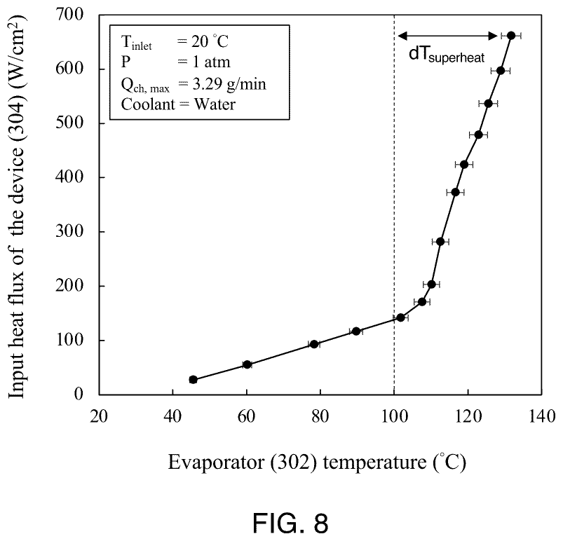

FIG. 8 shows the performance curve (the evaporator temperature vs. input heat flux) of our capillary microcooler in one experiment. This result shows incredibly high heat flux of ˜700 W/cm², of which the superheat is ˜30° C. (which is dTₛᵤₚₑᵣₕₑₐₜ), resulting in an extremely low two-phase thermal resistance of microcooler at ˜0.043 cm2-° C./W. The required flow rate to achieve such a cooling performance is less than 5 g/min . . . (Q_{ch, max}=3.29 g/min).

1. Apparatus comprising:
a copper plate having open microchannels, wherein the microchannels and the copper plate have a surface coating of a hydrophilic dendrite wicking structure;
a passive recirculation apparatus configured to receive output liquid coolant and output coolant vapor from the copper plate, configured to condense the output coolant vapor at a heat sink, and configured to provide the received output liquid coolant and condensed coolant vapor to the copper plate as an input coolant supply;
wherein coolant flow into the open microchannels is capillary-driven.

2. The apparatus of claim 1, wherein 90% or more of the input coolant supply is condensed from coolant vapor at the heat sink.

3. The apparatus of claim 1, wherein a heat flux of 600 W/cm² or more is delivered to the heat sink from the copper plate at a flow rate of the input coolant supply of 5 g/min or less.

4. The apparatus of claim 1, wherein the coolant is water and wherein the apparatus is configured such that an operating temperature of the heat sink is 50° C. or more.

5. The apparatus of claim 1, wherein the coolant is CF₃CH₂CHF₂ and wherein the apparatus is configured such that an operating temperature of the heat sink is 10° C. or more.

6. The apparatus of claim 1, wherein the passive recirculation apparatus is configured as a sealed vapor chamber.

7. The apparatus of claim 1, wherein the apparatus is configured to be integrated with the back side of a direct bond copper substrate of a power electronics module.

8. The apparatus of claim 1, wherein the passive recirculation apparatus includes a sponge configured to act as a reservoir.

9. The apparatus of claim 8, wherein the sponge is a porous polyurethane sponge.

10. The apparatus of claim 1, wherein the microchannels have a width for coolant flow at least 10× a thickness of the hydrophilic dendrite wicking structure.

11. The apparatus of claim 1, further comprising a coolant flow structure disposed on top of the open microchannels.

12. The apparatus of claim 11, wherein the coolant flow structure comprises one or more metal mesh layers.

13. The apparatus of claim 12, wherein the one or more metal mesh layers include one or more vent regions of reduced mesh density, and wherein the vent regions are disposed to coincide with hot spots from operation of one or more heat-generating devices.

14. The apparatus of claim 12, wherein the one or more metal mesh layers have a total thickness that is larger than 2× a depth of the open microchannels.

15. The apparatus of claim 12, wherein the one or more metal mesh layers have a total thickness that is larger than 50× a thickness of the hydrophilic dendrite wicking structure.
